(19) United States
(12) Patent Application Publication
(10) Pub. No.: US 2026/0331341 A1
(43) Pub. Date: Oct. 22, 2026

(54) SYSTEMS FOR TUNING AND CONTROLLING THE PROPAGATION OF A VIBRATION WAVE USING MAGNETS

(71) Applicant: Toyota Motor Engineering & Manufacturing North America, Inc., Plano, TX (US)

(72) Inventor: Taehwa Lee, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 19/182,846

(22) Filed: Apr. 18, 2025

(51) Int. Cl. H01F 7/02; H03H 9/02

(52) U.S. Cl. CPC H01F 7/0205; H03H 9/02

(57) ABSTRACT

Systems described herein relate to a device that tunes and controls a vibration wave using a magnetic lattice having cantilevers that adapt tuning and sensing. In one embodiment, a system includes disc magnets having cantilevers that are flexible, and the disc magnets form a zigzag pattern. The system also includes a first group from the disc magnets that are internally coupled with repulsive forces. The system also includes a second group from the disc magnets that are internally coupled with the repulsive forces. The system also includes the first group and the second group being externally coupled together. The system also includes a controller that causes an orientation change of the cantilevers between the first group and the second group. The system also includes that the orientation change tunes the disc magnets to a vibration at a frequency associated with an acoustic wave.

### TECHNICAL FIELD

The subject matter described herein relates, in general, to a system that controls the propagation of an vibration wave upon a disturbance, and, more particularly, to an array of magnets tuning and controlling the propagation with a cantilever and magnetic coupling.

### BACKGROUND

Systems transmitting a vibration wave through various mediums involve causing particles to vibrate in a travel direction. These vibrations create regions of compression and rarefaction that propagate the wave. For a sound wave, speed and efficiency depend upon material properties. For instance, sound travels faster in solids and liquids than in gases due to particle density. Systems perceive and transmit sound waves depending upon a frequency, a wavelength, and an amplitude for the sound waves. Boundaries and interfaces within media can reflect, refract, or absorb sound waves, also affecting propagation characteristics.

In various implementations, systems utilize magnets for tuning to a vibration wave using magnetoelastic effects. For example, magnetostriction involves magnetic materials changing shape and dimensions in response to magnetic fields. These changes can tune to vibration waves. Systems implementing magnetic materials for various applications (e.g., sensing, signal processing, and communication technologies) encounter diverse difficulties. For instance, longitudinal waves involve particle displacement parallel to a wave direction that is less impacted by magnetic fields compared to transverse waves. Furthermore, magnetostriction is more effective and efficient when generating and sensing transverse waves rather than longitudinal waves due to physical properties. Thus, systems relying upon magnets and magnetic fields for vibration wave applications encounter various technical challenges and complexities.

### SUMMARY

In one embodiment, example systems and embodiments relate to a device that tunes and controls a vibration wave using a magnetic lattice having cantilevers that adapt transmission, absorption, and sensing. In various implementations, systems utilizing magnets for tuning to a vibration wave using magnetoelastic effects involve complex physical interactions. For example, a system observes magnetoelastic Fano resonances when acoustic waves interact with magnetic spin waves and magnets couple. A system can manipulate the wave propagation through altering coupling using a controller. This magnetoelastic interaction is associated with nonreciprocal transmission involving longitudinal waves traveling in one direction while being blocked in the opposite direction, thereby enhancing filters and isolators. Still, controllers that change the orientation of magnets in systems encounter power losses and frequency offsets when tuning with a vibration wave, thereby hindering system performance.

Therefore, in one embodiment, a system tunes and controls wave propagation using disc magnets forming an elastic lattice and cantilevers coupled to the lattice alter the wave propagation. In one approach, groups of the disc magnets within the elastic lattice are magnetically coupled through repulsive forces that tune to the wave upon a disturbance. Regarding geometries, the cantilevers may have a quadrangular shape that increases flexibility and improves adjusting the repulsive forces between the groups. Furthermore, a controller coupled to the cantilevers changes the orientation of the groups for controlling the wave propagation. Here, an orientation change causes a tuning at a frequency through the disc magnets for an acoustic wave. In this way, the system offers enhanced control over wave characteristics, improves efficiency, and expands applications for systems demanding precise wave manipulation.

In one embodiment, a system that tunes and controls a vibration wave using a magnetic lattice having cantilevers that adapt tuning and sensing is disclosed. The system includes disc magnets having cantilevers that are flexible, and the disc magnets form a zigzag pattern. The system also includes a first group from the disc magnets that are internally coupled with repulsive forces. The system also includes a second group from the disc magnets that are internally coupled with the repulsive forces, and the first group has a unit cell represented by an elliptical shape and the second group is represented by the elliptical shape. The system also includes the first group and the second group being externally coupled together. The system also includes a controller that causes an orientation change of the cantilevers between the first group and the second group. The system also includes that the orientation change tunes the disc magnets to a vibration at a frequency associated with an acoustic wave.

In one embodiment, a system that tunes and controls a vibration wave using a magnetic lattice having cantilevers that adapt tuning and sensing is disclosed. The system includes disc magnets having cantilevers that are flexible, and the disc magnets form a linear pattern and the cantilevers have a rectangular shape and the rectangular shape has a long profile and a thin profile. The system also includes a first group from the disc magnets that are internally coupled with repulsive forces. The system also includes a second group from the disc magnets that are internally coupled with the repulsive forces, and the first group has a unit cell with a rectangular shape and the second group has the rectangular shape. The system also includes that the first group and the second group are externally coupled together with the repulsive forces. The system also includes a controller that causes an orientation change of the cantilevers between the first group and the second group. The system also includes that the orientation change tunes the disc magnets to a vibration at a frequency associated with an acoustic wave.

In one embodiment, a system that tunes and controls a vibration wave using a magnetic lattice having cantilevers that adapt tuning and sensing is disclosed. The system includes disc magnets having cantilevers that are flexible, and the disc magnets form a zigzag pattern and the cantilevers have a rectangular shape and the rectangular shape has a long profile and a thin profile. The system also includes a first group from the disc magnets that are internally coupled with repulsive forces. The system also includes a second group from the disc magnets that are internally coupled with the repulsive forces, and the first group has a unit cell with an elliptical shape and the second group has the elliptical shape. The system also includes that the first group and the second group are externally coupled together with the repulsive forces. The system also includes a controller that causes an orientation change of the cantilevers between the first group and the second group. The system also includes that the orientation change tunes the disc magnets to a vibration at a frequency associated with an acoustic wave, the acoustic wave propagates at end boundaries of the first group and the second group.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIGS. 1A-1C illustrate embodiments of a system having disc magnets arranged in a zigzag pattern for wave tuning and controlling wave propagation using cantilevers.

FIGS. 2A and 2B illustrate embodiments of a system having disc magnets arranged in a linear pattern for wave tuning and controlling wave propagation using cantilevers.

FIG. 3 illustrates an example of a relationship between magnetic coupling strengths and cantilever orientation.

FIGS. 4A and 4B illustrate examples of a dispersion relation between frequency and wavelength using the system.

### DETAILED DESCRIPTION

Systems and other embodiments associated with a device that controls and tunes to a vibration wave from a disturbance using a magnetic lattice having cantilevers that adapt sensing through orientation changes are disclosed herein. In various implementations, systems detect and propagate a longitudinal wave using magnets tuned through altering the material properties of the magnets. Systems altering material and physical properties of magnets can be complex and lead to difficulties in achieving consistent and precise tuning of a vibration wave, thereby reducing system reliability.

Therefore, in one embodiment, a system includes disc magnets forming a zigzag pattern coupled to flexible cantilevers having a rectangular shape that improve adjusting of the disc magnets for vibration wave absorption, propagation, and tuning. Here, individual disc magnets can be internally coupled with repulsive forces in a spring model and form a unit cell with a cantilever representing building blocks. For instance, an elliptical shape indicates a two magnets-on-cantilever configuration within a unit cell. Furthermore, disc magnet groups can be externally coupled with repulsive forces. In one approach, a controller coupled to the cantilevers causes an orientation change of the disc magnets. The orientation change can tune the system to a frequency through the disc magnets for an acoustic wave. For wave sensing and tuning, the acoustic wave can propagate within the disc magnets upon a disturbance to the disc magnets. In certain applications, the acoustic wave forms at the boundaries of the disc magnets, such as to reduce interference with components above and below the disc magnets. Therefore, the system includes a device as a tuning mechanism that achieves simplicity and efficiency through modifying cantilever orientation, thereby improving performance while reducing complexity when sensing and tuning to vibration waves.

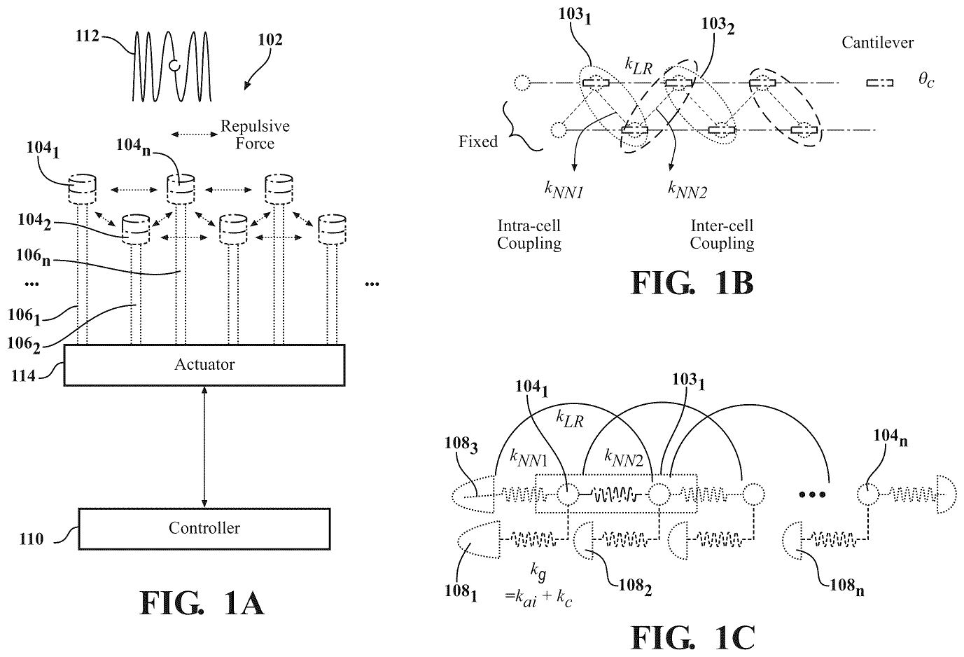

FIGS. 1A and 1B illustrate embodiments of a system having disc magnets 104₁, 104₂, . . . , 104ₙ arranged in a zigzag pattern for wave tuning and controlling wave propagation using cantilevers. In system 102, a device includes the disc magnets 104₁-104ₙ having cantilevers 106₁, 106₂, . . . , 106ₙ that are flexible. Although the examples herein reference disc magnets, the system can implement other shapes for the disc magnets 104₁-104ₙ including one of a bar shape, a cylindrical shape, a ring shape, and a spherical shape. Here, the top half of the disc magnets 104₁-104ₙ can be the north pole while the bottom is the south pole. In other embodiments, the disc magnets 104₁-104ₙ can have a polarity that is reversed between the top and the bottom halves. The disc magnets 104₁-104ₙ can form the zigzag pattern where a first group 103₁ from the disc magnets 104₁-104ₙ are internally coupled with repulsive forces. A second group 103₂ from the disc magnets 104₁-104ₙ are internally coupled with repulsive forces. Furthermore, the first group 103₁ and the second group 103₂ have unit cells with an elliptical shape.

As further explained below, the first group 103₁ and the second group 103₂ can be externally coupled together with repulsive forces. In another approach, a controller 110 causes an orientation change of the cantilevers 106₁-106ₙ between the first group 103₁ and the second group 103₂ that alters repulsive forces. Here, the orientation change adjusts coupling between the disc magnets 104₁-104ₙ for tuning to a vibration wave 112. In the examples given herein, the vibration wave 112 can be one of an acoustic wave, a sound wave, a sound transmission, a sonic wave, a pressure wave, a vibration wave, a plate wave, an audio wave, a mechanical wave, a longitudinal wave, a traverse wave, etc. Transverse waves propagate along an x-direction when magnets vibrate in a y-direction. Longitudinal waves propagate along the x-direction when magnets vibrate in the x-direction.

In FIG. 1A, the cantilevers 106₁-106ₙ may be thin and flexible and the disc magnets 104₁-104ₙ are coupled at the ends of the cantilevers 106₁-106ₙ. A cantilever can be a structure supported at one end that is projected outward (e.g., horizontally, vertically, etc.) without additional support. A cantilever can be formed with one of a beam, a plate, a truss, and a slab. In another approach, the disc magnets 104₁-104ₙ are located at positions other than the ends. Furthermore, the material of the cantilevers 106₁-106ₙ can be one of plastic, a flexible plastic, a non-magnetic metal, aluminum, etc. In this way, the system 102 allows differences in bending stiffnesses depending on one of a direction (e.g., x-y), an angle, etc. As such, an orientation change is a bend of the cantilevers 106₁-106ₙ that may impact disturbances and wave propagation. A stiffness value of the bend is associated with a long profile and a thin profile.

The system 102 has a magnet-on-cantilever structure arranged in a zigzag pattern. For example, the zigzag pattern is one of an offset pattern and a lattice pattern. Furthermore, vibrating one of the disc magnets 104₁-104ₙ impacts other magnets and generates an acoustic that propagates within and through the lattice, such as through vibrations caused by changes in the repulsive forces by a vehicle, road, etc. In one approach, an actuator 114 coupled to the cantilevers 106₁-106ₙ causes an orientation change responsive to one of a signal, a trigger signal, and a motion signal communicated by the controller 110. The actuator 114 can be one of a hydraulic actuator, a pneumatic actuator, an electric motor, an electric actuator, a thermal actuator, and a piezoelectric actuator.

In the system 102, the cantilevers 106₁-106ₙ can have a rectangular shape and the rectangular shape has one of an extended profile (e.g., a wide length) and a long profile and a thin profile. Here, the rectangular shape allows differences in bending stiffnesses depending on one of a direction (e.g., x-y), an angle, etc., of the cantilevers 106₁-106ₙ. For instance, the cantilevers 106₁-106ₙ manufactured with a long width and minimal thickness improve bending capabilities when the disc magnets 104₁-104ₙ are subjected to repulsive forces. This configuration can generate the vibration wave 112 from a disturbance that propagates within the first group 103₁ and the second group 103₂ during one of sensing and tuning for the vibration wave 112. The disturbance can be external such as road noise, a pothole, etc., when the system 102 is installed on a vehicle.

In another example, the disc magnets 104₁-104ₙ are oriented in the same direction and generate repulsive forces between neighboring disc magnets. For instance, the disc magnets 104₁-104ₙ in the first group 103₁ can face a same direction that causes the repulsive forces. Furthermore, the cantilevers 106₁-106ₙ can have a rectangular cross-section width w₁ and height w₂ such that w₁»w₂. This geometry produces various bending stiffnesses depending on a bending direction, a bending angle, etc. For a cantilever length of L and Young's modulus E, the bending stiffness is given by deflection in the direction of w₁:

$${k}_{1} = \frac{E {w}_{2} {w}_{1}^{3}}{4 {L}^{3}} . \qquad Equation ( 1 )$$

A deflection in the direction of w₂ gives:

$${k}_{2} = \frac{E {w}_{1} {w}_{2}^{3}}{4 {L}^{3}} . \qquad Equation ( 2 )$$

In another example, the variable k can represent one of a spring constant and a material stiffness. This allows the system 102 to tune coupling and adjust strengths by changing cantilever orientation. For instance, the tilt angle is represented by θ_{c}. As such, the orientation change is one of a change in a horizontal direction, a rotation angle, and the tilt angle θ_{c}. This can result in the acoustic wave having a frequency related to one of the tilt angle and direction of the cantilevers 106₁-106ₙ.

In FIG. 1B, the first group 103₁ for a unit cell includes two disc magnets exhibiting the following coupling strengths: k_{NN1} (intra-cell coupling), k_{NN2} (inter-cell coupling), and k_{LR} (long range coupling) left-right coupling). In the examples given here, NN is associated with couplings between nearest neighbors among the disc magnets 104₁-104ₙ for different intra-cell and inter-cell couplings. Furthermore, an elliptical shape can represent a two magnets-on-cantilever unit cell. The unit cell can be associated with a magnetic polarity of the disc magnets 104₁-104ₙ. Although this example includes a unit cell represented by an elliptical shape, the system 102 can be reconfigured to adopt different combinations of magnet-on-cantilevers patterns.

FIG. 1C shows a mass-spring model that physically represents the system 102. Here, a coupling between magnets can be represented by k_{NN2}. A coupling between unit cells can be represented by k_{NN1}. In yet another example, a variable k_{g} represents stiffness for ground springs 108₁, 108₂, . . . , 108ₙ. The variable k_{c} can represent a cantilever stiffness associated with k₁ and k₂ and an orientation of the cantilevers 106₁-106ₙ. The variable kₐᵢ can represent stiffness for fixed magnets. Accordingly, the system 102 derives k_{g} as:

k_{g}=kₐᵢ+k_{c}. Equation (3)

The system 102 may have various configurations. For instance, the disc magnets 104₁-104ₙ have the cantilevers 106₁-106ₙ that are flexible and the disc magnets 104₁-104ₙ form a zigzag pattern. The cantilevers 106₁-106ₙ can have a rectangular shape such that the rectangular shape has a long profile and a thin profile. In an embodiment, the rectangular shape allows differences in bending stiffnesses depending on one of a direction (e.g., x-y), an angle, etc. For instance, the cantilevers 106₁-106ₙ being produced with a long width and minimal thickness improves bending capabilities when the disc magnets 104₁-104ₙ are subjected to repulsive forces.

Moreover, the first group 103₁ forming the disc magnets 104₁-104ₙ can be internally coupled with repulsive forces. A second group 103₂ forming the disc magnets 104₁-104ₙ can be internally coupled with the repulsive forces. Here, the first group 103₁ has a unit cell indicated with an elliptical shape representing a two magnets-on-cantilever configuration. The second group 103₂ also has the elliptical shape. In another example, the first group 103₁ and the second group 103₂ are externally coupled together with the repulsive forces. Although this example exhibits a two magnets-on-cantilever configuration, the system 102 can be reconfigured to adopt different configurations using cantilevers and magnets.

Moreover, the controller 110 can cause an orientation change of the cantilevers 106₁-106ₙ between the first group 103₁ and the second group 103₂ that impact wave tuning and sensing. In this example, the orientation change tunes at a frequency through the disc magnets 104₁-104ₙ through physical displacement. The acoustic wave may form from the vibration at end boundaries of the first group and the second group. In another example, the acoustic wave permeates among and between the disc magnets 104₁-104ₙ for omnidirectional perception. Here, the lattice attaches as an intermediate medium to control vibration waves. Another example includes an entire lattice being excited from a base that causes a vibration either as an edge-localized vibration and an entire-lattice vibration depending on the orientation of the lattice.

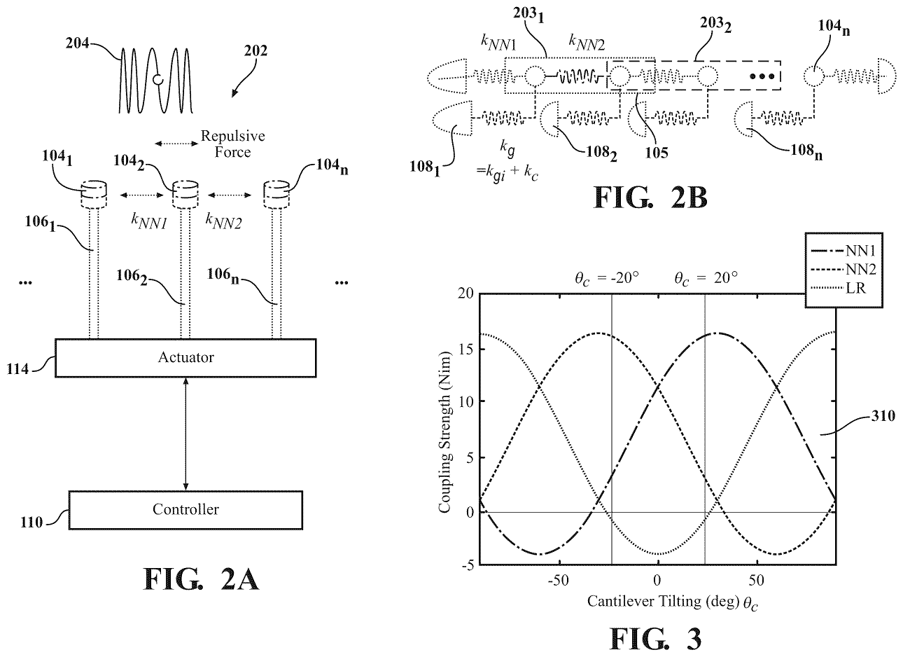

Now turning to FIGS. 2A and 2B, a system 202 having the disc magnets 104₁-104ₙ arranged in a linear pattern for wave tuning and controlling wave propagation using the cantilevers 106₁-106ₙ are illustrated. In one approach, the linear pattern is one of a line, a straight line, and a directional line. Here, the disc magnets 104₁-104ₙ have the cantilevers 106₁-106ₙ exhibiting flexible properties and form the linear pattern. In another approach, the cantilevers 106₁-106ₙ have a rectangular shape and the rectangular shape has a long profile and a thin profile. In an example, the rectangular shape allows differences in bending stiffnesses depending on one of a direction (e.g., x-y), an angle, etc. For instance, the cantilevers 106₁-106ₙ produced with a long width and minimal thickness improves bending capabilities when the disc magnets 104₁-104ₙ are subjected to repulsive forces. Furthermore, the system 202 has a first group 2031 from the disc magnets 104₁-104ₙ internally coupled with repulsive forces. The second group 2032 from the disc magnets 104₁-104ₙ can also be internally coupled with the repulsive forces.

FIG. 2B shows a mass-spring model physically representing the system 202. The first group 2031 in this example has a unit cell with a rectangular shape and the second group 2032 has the rectangular shape. The unit cell can be associated with a magnetic polarity of the disc magnets 104₁-104ₙ. The second group 2032 from the disc magnets 104₁-104ₙ can be internally coupled with the repulsive forces. The first group 2031 and the second group 2032 can be externally coupled together with the repulsive forces. Furthermore, coupling 105 indicates additional forces combining internal and external coupling.

In another approach, the controller 110 causes an orientation change of the cantilevers 106₁-106ₙ between the first group 2031 and the second group 2032. Here, the orientation change improves tuning with a vibration wave at a frequency through the disc magnets 104₁-104ₙ. A vibration wave 204 forms from the vibration associated with changes in environmental pressure (e.g., water pressure, air pressure, etc.). Similar to prior descriptions, the vibration wave 204 can be one of an acoustic wave, a sound wave, a sound transmission, a sonic wave, a pressure wave, a vibration wave, a plate wave, an audio wave, a mechanical wave, a longitudinal wave, etc.

Regarding applications, the systems 102 and 202 can modulate information on the vibration wave 204. In another example, the system 102 can tune to sense vibration energy from the vibration wave 204 during a disturbance to the lattice. For example, the controller 110 communicates the sensed energy to another system for demodulation. This can assist sensor systems in consumer devices, vehicles, etc., to measure environmental conditions adaptively by changing the orientation of the disc magnets 104₁-104ₙ.

FIG. 3 illustrates an example of a relationship between coupling strengths and cantilever orientation in chart 310. Here, the angle θ_{c} can be an orientation change that is one of rotational, horizontal, etc. The orientation change can be caused by the actuator 114 or manually moving the cantilevers 106₁-106ₙ. The zigzag lattice can tune coupling strengths by varying the angle 0° C. For instance, the system 102 selectively prohibits wave propagation when 0, is a tilt angle of −20° or 20°. For 20°, the vibration energy is localized at both ends (i.e., at the lattice boundaries). For −20°, the vibration energy is dissipated without localization at the edges. Chart 310 also illustrates that a positive angle for θ_{c} can result in k_{NN1} and k_{LR} couplings being more than k_{NN2}. Correspondingly, a negative angle for θ_{c} can result in k_{NN2} and k_{LR} couplings being more than k_{NN1}. As such, a vibration wave can be selectively controlled by manipulating couplings among the disc magnets 104₁-104ₙ.

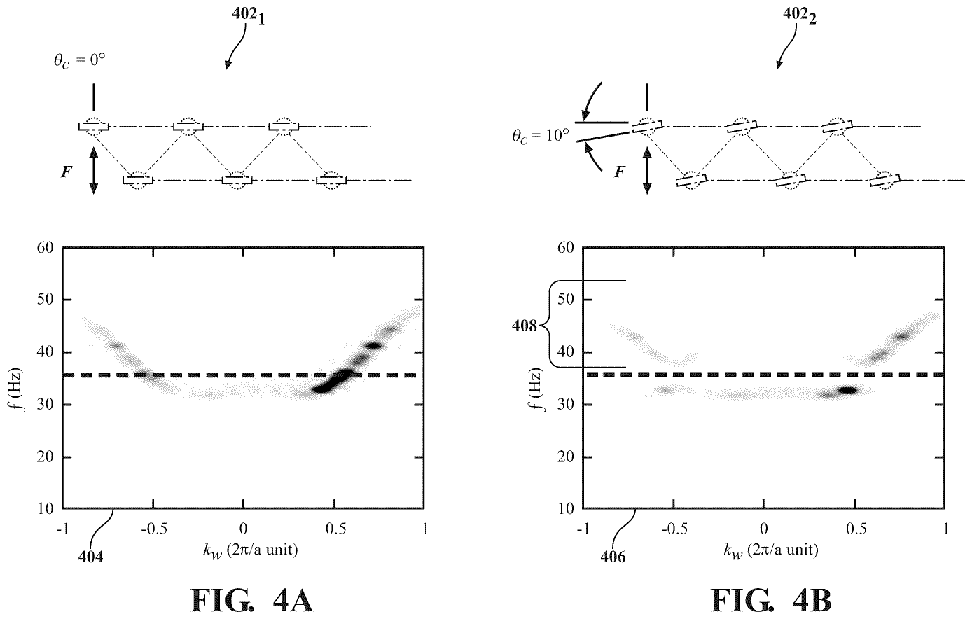

Regarding FIGS. 4A and 4B, examples of a dispersion relation between frequency and wavelength using the system are illustrated. Charts 404 and 406 demonstrate allowable frequencies for various wavelengths associated with the vibration wave 112 generated by the system 102 or the vibration wave 204 generated by the system 202. The x-axis 2π/a is a unit for a wave number kw related to the spacing and structure of the disc magnets 104₁-104ₙ. Here, wave dispersion can be adjusted by changing the angle θ_{c} for one or more of the disc magnets 104₁-104ₙ. In FIG. 4A, a configuration 4021 has a horizontal orientation with a tilt angle θ_{c}=0 for a lattice including the disc magnets 104₁-104ₙ. The configuration 4021 exhibits a continuous dispersion in chart 404 between various frequencies and wavelengths. A dashed line indicates that the vibration wave 112 or the vibration wave 204 at a frequency of 35 Hz can propagate through a lattice.

Moreover, FIG. 4B illustrates that the configuration 4022 having a tilt angle θ_{c}=10 for the disc magnets 104₁-104ₙ using the cantilevers 106₁-106ₙ exhibits a discontinuous dispersion. Here, wave propagation is hindered at the frequency 35 Hz. In particular, the systems 102 and 202 have tuning modes that disallow propagation at 35 Hz at certain orientations and angles. Thus, frequencies for wave propagation can be controlled by the cantilevers 106₁-106ₙ changing the orientation of the disc magnets 104₁-104ₙ.

The systems 102 and 202 can also localize waves for one of energy harvesting, vibrating isolation, vibration isolation, etc., at the ends and boundaries of the disc magnets 104₁-104ₙ depending upon θ_{c}. For instance, the disc magnets 104₁-104ₙ having 20 magnets at θ_{c}=−30° can define an edge mode. An entire lattice being excited from a base can cause a vibration that is a localized vibration at the edges of the lattice for the edge mode. The systems 102 and 202 with this configuration can sense and receive the vibration wave 112 in a certain direction and frequency at one end of the disc magnets 104₁-104ₙ. Meanwhile, wave tuning, sensing, and receiving are hindered by the systems 102 and 202 at the other end of the disc magnets 104₁-104ₙ.

FIG. 4B shows a bandgap 408 associated with an edge mode that prevents wave propagation at certain frequencies and orientations associated with the disc magnets 104₁-104ₙ. Chart 406 illustrates that both positive and negative orientation changes for θ_{c} can prohibit wave propagation. The cantilevers 106₁-106ₙ causing a precise positive orientation change exhibit energy localization at a boundary location. However, a negative orientation dissipates a vibration without a wave propagating at a different boundary location. Accordingly, the system includes a device that accurately and simply tunes to vibration waves through modifying cantilever orientation, thereby reducing system complexity and increasing system performance.

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-4, but the embodiments are not limited to the illustrated structure or application.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A system comprising:
disc magnets having cantilevers that are flexible, and the disc magnets form a zigzag pattern;
a first group from the disc magnets are internally coupled with repulsive forces;
a second group from the disc magnets are internally coupled with the repulsive forces, and the first group has a unit cell represented by an elliptical shape and the second group is represented by the elliptical shape;
the first group and the second group being externally coupled together;
a controller causes an orientation change of the cantilevers between the first group and the second group; and
the orientation change tunes the disc magnets to a vibration at a frequency associated with an acoustic wave.

2. The system of claim 1 further comprising:
an actuator coupled to the cantilevers and the actuator causes the orientation change responsive to a trigger signal communicated by the controller;
the cantilevers have a rectangular shape and the rectangular shape has an extended profile and a thin profile; and
the acoustic wave propagates within the first group and the second group during one of sensing and tuning for the acoustic wave.

3. The system of claim 2, wherein:
the orientation change is a bend of the cantilevers; and
a stiffness value of the bend is associated with a long profile and the thin profile.

4. The system of claim 2, wherein:
the orientation change is one of a change in a horizontal direction, a rotation angle, and a tilt angle; and
the acoustic wave has a frequency related to the tilt angle.

5. The system of claim 1, wherein the disc magnets in the first group face a same direction that causes the repulsive forces.

6. The system of claim 1, wherein:
the unit cell is associated with a magnetic polarity of the disc magnets; and
the vibration is caused by a disturbance from one of a road noise and a pothole.

7. The system of claim 1, wherein the zigzag pattern is one of an offset pattern and a lattice pattern.

8. A system comprising:
disc magnets having cantilevers that are flexible, and the disc magnets form a linear pattern and the cantilevers have a rectangular shape and the rectangular shape has a long profile and a thin profile;
a first group from the disc magnets are internally coupled with repulsive forces;
a second group from the disc magnets are internally coupled with the repulsive forces, and the first group has a unit cell represented by a rectangular shape and the second group has the rectangular shape;
the first group and the second group being externally coupled together with the repulsive forces;
a controller causes an orientation change of the cantilevers between the first group and the second group; and
the orientation change tunes the disc magnets to a vibration at a frequency associated with an acoustic wave.

9. The system of claim 8 further comprising:
an actuator coupled to the cantilevers and the actuator causes the orientation change responsive to a signal communicated by the controller; and
the acoustic wave propagates within the first group and the second group during one of sensing and tuning for the acoustic wave.

10. The system of claim 9, wherein:
the orientation change is a bend of the cantilevers; and
a stiffness value of the bend is associated with the long profile and the thin profile.

11. The system of claim 9, wherein:
the orientation change is one of a change in a horizontal direction, a rotation angle, and a tilt angle; and
the acoustic wave has a frequency related to the tilt angle.

12. The system of claim 8, wherein the disc magnets in the first group face a same direction that causes the repulsive forces.

13. The system of claim 8, wherein:
the unit cell is associated with a magnetic polarity of the disc magnets; and
the vibration is caused by a disturbance from one of a road noise and a pothole.

14. The system of claim 8, wherein the linear pattern forms a straight line.

15. A system comprising:
disc magnets having cantilevers that are flexible, and the disc magnets form a zigzag pattern and the cantilevers have a rectangular shape and the rectangular shape has a long profile and a thin profile;
a first group from the disc magnets are internally coupled with repulsive forces;
a second group from the disc magnets are internally coupled with the repulsive forces, and the first group has a unit cell indicated by an elliptical shape and the second group is indicated by the elliptical shape;
the first group and the second group being externally coupled together with the repulsive forces;
a controller causes an orientation change of the cantilevers between the first group and the second group; and
the orientation change tunes the disc magnets to a vibration at a frequency associated with an acoustic wave, the acoustic wave propagates at end boundaries of the first group and the second group.

16. The system of claim 15 further comprising:
the controller communicates a motion signal to an actuator coupled with the cantilevers; and
the actuator causes the orientation change responsive to the motion signal; and
the acoustic wave propagates within the first group and the second group during one of sensing and tuning for the acoustic wave.

17. The system of claim 16, wherein:
the orientation change is a flexing of the cantilevers; and
a stiffness value of the flexing is associated with the long profile and the thin profile.

18. The system of claim 16, wherein:
the orientation change is one of a change in a horizontal direction, a rotation angle, and a tilt angle; and
the acoustic wave has a frequency related to the tilt angle.

19. The system of claim 15, wherein the disc magnets in the first group face a same direction that causes the repulsive forces.

20. The system of claim 15, wherein the zigzag pattern is one of an offset pattern and a lattice pattern.
